(19) United States
(12) Patent Application Publication
(10) Pub. No.: US 2012/0086449 A1
(43) Pub. Date: Apr. 12, 2012

(54) MAGNETIC RESONANCE SYSTEM AND METHOD FOR COMPREHENSIVE IMPLANTABLE DEVICE SAFETY TESTS AND PATIENT SAFETY MONITORING

(75) Inventors: Ingmar Graesslin, Boenningstedt (DE); Sascha Krueger, Hamburg (DE)

(73) Assignee: KONINKLIJKE PHILIPS ELECTRONICS N.V., EINDHOVEN (NL)

(21) Appl. No.: 13/260,918

(22) PCT Filed: Mar. 31, 2010
(86) PCT No.: PCT/IB2010/051398

§ 371 Date: Dec. 13, 2011

(30) Foreign Application Priority Data
Apr. 1, 2009 (EP) 09157052.3

(51) Int. Cl. G01R 33/44; G01R 33/32

(52) U.S. Cl. 324/309; 324/318

(57) ABSTRACT

A magnetic resonance method comprises: performing (C1) a magnetic resonance procedure on a calibration subject including an implant device; detecting (C2) a pick-up coil (PUC) signal at least during a radio frequency transmit phase of operation (C1); performing (C3) three dimensional temperature mapping of the calibration subject using a magnetic resonance sequence configured to detect any temperature change induced in any part of the implant device by operation (C1); generating (C4) an unsafe condition criterion (30) for the detected PUC signal based on correlating a PUC signal characteristic detected by operation (C2) with a temperature change detected by operation (C3); performing (M5) the magnetic resonance procedure on a subject containing an implant device; detecting (M6) a PUC signal at least during a radio frequency transmit phase of operation (M5); and monitoring (M7) for an unsafe condition indicated by the PUC signal detected in operation (M6) satisfying the unsafe condition criterion (30).

### FIELD OF THE INVENTION

The following relates to the magnetic resonance arts. The following finds illustrative application to magnetic resonance imaging and spectroscopy, and is described with particular reference thereto. However, the following will find application in other magnetic resonance applications.

### BACKGROUND OF THE INVENTION

A difficulty with diagnostic or clinical application of magnetic resonance (MR) for imaging or the like is incompatibility with certain implant devices. Such implant devices can be permanent or semi-permanent, such as a cardiac pacemaker, orthopedic joint implant, or the like; or can be a temporarily inserted implant device such as an interventional instrument (for example, a catheter or biopsy needle).

For the purpose of MR safety, implant devices are typically classified as one of: “MR safe” which means the implant contains no metal or other electrically conductive material; “MR conditional” which means the implant contains at least some electrically conductive material but has nonetheless been assessed to be safe for MR (i.e., safe for use in an MR environment) at least under certain constraints; and “MR unsafe” which means the implant contains at least some electrically conductive material and is considered incompatible with MR. In the case of MR conditional implant devices, one condition typically relates to the static magnetic field strength. For example, an MR conditional device may be deemed safe for MR imaging employing a 1.5 Tesla magnetic field, but deemed not safe for MR imaging employing a 3 Tesla or higher magnetic field. Other conditions may relate to the specific absorption rate (SAR) generated by the MR sequence, the maximum magnetic field gradient slew rate, or so forth. For MR sequence-dependent conditions, it may be difficult to determine whether or not the implant device is compatible with a given MR sequence performed using a particular set of sequence parameters.

Moreover, an MR conditional implant device that is generally considered to be safe for a given MR sequence operating with a given set of parameters may become unsafe if the implant device is somehow different from its assumed configuration. For example, an MR conditional cardiac pacemaker that is safe for a given MR procedure may become unsafe if one of the electrical leads of the pacemaker is broken. Also, apparently identical implant devices may have very different response to MR excitation if one device happens to have a natural resonant frequency exactly matching the magnetic resonance frequency while the other device happens to have a natural resonant frequency that is slightly “off-resonance” respective to the magnetic resonance frequency.

A principle risk in MR conditional or MR unsafe devices is that the electromagnetic fields generated by an MR procedure may induce electrical current flow in an electrically conductive portion of the implant device which may in turn lead to localized heating in the vicinity of the electrically conductive portion of the implant device. Because the implant device is internal to the subject, it has heretofore been difficult or impossible to dynamically assess whether the MR is interacting with the implant device to generate an unsafe condition.

It is known to detect implant device heating by monitoring a temperature sensor disposed with (e.g., embedded in or attached to) the implant device. This approach has deficiencies. For example, it increases complexity of the implant device, and also provides only a localized temperature measurement that may fail to detect localized heating of a part of the implant device located away from the temperature sensor. Moreover, it is usually considered unsafe to allow any heating of the implant device in a patient, archaeological mummy, or other sensitive subject. As a result, by the time the temperature sensor detects heating an unsafe condition may already exist.

### SUMMARY OF THE INVENTION

In accordance with certain illustrative embodiments shown and described as examples herein, a magnetic resonance method comprises: (i) performing a magnetic resonance procedure on a calibration subject; (ii) detecting a pick-up coil (PUC) signal at least during a radio frequency transmit phase of operation (i); and (iv) generating an unsafe condition criterion for the detected PUC signal based on a PUC signal characteristic detected by operation (ii).

In accordance with certain illustrative embodiments shown and described as examples herein, a magnetic resonance method comprises: (v) performing a magnetic resonance procedure on a subject containing an implant device; (vi) detecting a PUC signal at least during a radio frequency transmit phase of operation (v); and (vii) monitoring for an unsafe condition during the operation (v) indicated by the PUC signal detected in operation (vi) satisfying an unsafe condition criterion.

In accordance with certain illustrative embodiments shown and described as examples herein, a safety monitor is disclosed which is configured to perform the operations set forth in the immediately preceding paragraph. In accordance with certain illustrative embodiments shown and described as examples herein, a storage medium is disclosed which stores instructions executable by a digital processor to perform the operations set forth in one or both of the immediately preceding two paragraphs. In accordance with certain illustrative embodiments shown and described as examples herein, a magnetic resonance system is disclosed comprising a magnetic resonance scanner and a processor configured to operate in cooperation with the magnetic resonance scanner to perform a magnetic resonance method as set forth in one or both of the immediately preceding two paragraphs.

One advantage resides in rapid assessment of incipient implant device heating over the entire volume of the implant device.

Another advantage resides in simultaneous real-time safety monitoring of all parts of the implant device.

Another advantage resides in providing safety monitoring with a reduced likelihood of missing localized heating.

Still further advantages will be appreciated by those of ordinary skill in the art upon reading and understand the following detailed description.

### BRIEF DESCRIPTION OF THE DRAWINGS

The drawings are only for purposes of illustrating the preferred embodiments, and are not to be construed as limiting the invention. Corresponding reference numerals when used in the various figures represent corresponding elements in the figures.

FIG. 1 diagrammatically shows a magnetic resonance system incorporating a safety monitor.

FIG. 2 diagrammatically shows a method suitably performed by the system of FIG. 1 to establish an unsafe condition indicator that is configured to detect an incipient unsafe condition in any part of an implant device.

FIG. 3 diagrammatically shows a method suitably performed by the system of FIG. 1 to monitor for an unsafe condition using the unsafe condition indicator generated by the method of FIG. 2.

FIG. 4 plots some experimental calibration data.

FIG. 5 plots some experimental subject data.

### DETAILED DESCRIPTION OF EMBODIMENTS

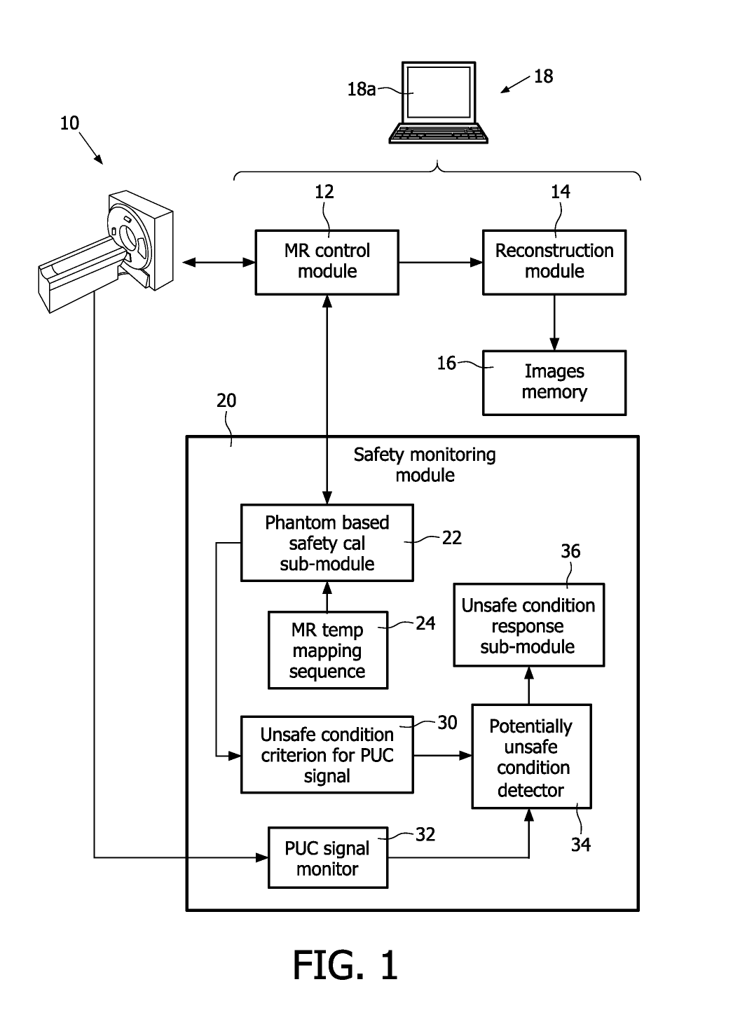

With reference to FIG. 1, a magnetic resonance system includes a magnetic resonance scanner 10, such as an illustrated Achieva™ magnetic resonance scanner (available from Koninklijke Philips Electronics N.V., Eindhoven, The Netherlands), or an Intera™ or Panorama™ magnetic resonance scanner (both also available from Koninklijke Philips Electronics N.V.), or another commercially available magnetic resonance scanner, or a non-commercial magnetic resonance scanner, or so forth. In a typical embodiment, the magnetic resonance scanner includes internal components (not illustrated) such as a superconducting or resistive main magnet generating a static (Bₒ) magnetic field, sets of magnetic field gradient coil windings for superimposing selected magnetic field gradients on the static magnetic field, a radio frequency excitation system for generating a radiofrequency (B₁) field at a frequency selected to excite magnetic resonance (typically ¹H magnetic resonance, although excitation of another magnetic resonance nuclei alternative to or in addition with the ¹H magnetic resonance is also contemplated), and a radio frequency receive system including a radio frequency receive coil, or an array of multiple radio frequency receive coils (e.g., two, three, four, eight, sixteen, or more coils), for detecting magnetic resonance signals emitted from the subject.

The magnetic resonance scanner 10 is controlled by a magnetic resonance control module 12 to execute a magnetic resonance sequence that generates a magnetic resonance excitation, performs spatial encoding typically generated by magnetic field gradients, and acquires magnetic resonance signal readout. For imaging, a reconstruction module 14 reconstructs acquired spatially encoded magnetic resonance signals to generate one or more magnetic resonance images that are stored in a magnetic resonance images memory 16. For other applications such as spectroscopy, other suitable post-acquisition processing (i.e., post-processing) hardware may be employed in addition to or in place of the reconstruction module 14. The components 12, 14, 16 are suitably embodied as software executing on a digital processor (not shown) of an illustrated computer 18, or as analog, digital, or hybrid application specific integrated circuitry (ASIC), or so forth.

To support safety monitoring when the subject includes an MR-conditional implant device, a safety monitoring module 20 is provided, which may for example be embodied as software executing on a digital processor of the illustrated computer 18. The MR-conditional implant device may be permanent or semi-permanent, such as a cardiac pacemaker, orthopedic joint implant, or the like, or can be a temporarily inserted implant device such as an interventional instrument (for example, a catheter or biopsy needle). In a typical example of the latter situation, the interventional instrument is employed during an interventional procedure that is monitored by magnetic resonance imaging performed by the magnetic resonance scanner 10 under control of the MR control module 12.

The safety monitoring implemented by the safety monitoring module 20 employs pick-up coil (PUC) signal monitoring. A pick-up coil is placed near the radio frequency receive coil, or pick-up coils are placed near each radio frequency receive coil element of a multi-channel coil array. Each pick-up coil is connected to a dedicated monitoring input for monitoring the PUC signals, so that the current of each coil element of the coil array can be monitored. During the transmit phase of a magnetic resonance sequence, the receive coils are typically detuned to avoid overloading of the receive coils. However, some electric current may be induced in the receive coils by the transmitted radio frequency pulse, pulses, or pulse packets, either in spite of the detuning or because of a failure of the detuning. This induced electric current is detected as a PUC signal by the pick-up coil or coils. Appropriate remedial action such as termination of the magnetic resonance sequence, replacement or repair of a detected malfunctioning receive coil, or so forth, may then be performed in response. The pick-up coils are also sometimes used for various system calibration purposes.

The PUC signal detected by the pick-up coil or coils is generally indicative of an electrical current induced by the transmit phase of the MR sequence that couples with the pick-up coil. As such, the PUC signal can be indicative of electrical current flowing in conductive parts of the implant device, since these electric currents may also couple with the pick-up coil. However, the amount of electromagnetic coupling between any given pick-up coil and an electrical current flowing in a conductive part of the implant device is complicated by factors such as coil-to-implant device distance, respective orientation of the electrical current flow and the pick-up coil, detailed geometry of the conductive part of the implant device, intervening tissue of the subject, or so forth. At the same time, because the implant device is disposed inside of the subject, any heating of any portion of the implant device during the MR procedure is generally considered to be a safety concern. Accordingly, the use of the PUC signal for safety monitoring of an implant device during an MR procedure depends upon reliably correlating a PUC signal characteristic with incipient heating of at least a part of the implant device.

Toward this end, the safety monitoring module 20 includes a safety calibration sub-module 22 that correlates (1) the PUC signal detected while a phantom or other calibration subject containing or otherwise including an implant device undergoes an MR procedure with (2) temperature as measured by a three-dimensional temperature mapping of the calibration subject using an MR sequence that is configured to detect a temperature change induced in any part of the implant device by the MR procedure. The sub-module 22 can employ substantially any suitable MR temperature mapping sequence 24, such as a proton resonance frequency (PRF) based MR temperature mapping sequence which operates based on known temperature dependence of the ¹H proton resonance frequency. Unlike an integral temperature sensor, the MR temperature mapping sequence maps the entire implant device, and thus detects a temperature rise of any part of the implant device even if the temperature rise is highly localized. The safety calibration sub-module 22 generates an unsafe condition criterion 30 for the detected PUC signal based on correlating a PUC signal characteristic of the detected PUC signal with a temperature change (typically a temperature increase) detected by the MR temperature mapping. The correlated PUC signal characteristic may, for example, include one or more of the following: PUC signal amplitude; PUC signal phase; coil-to-coil coupling between pick-up coils identified based on the plurality of PUC signals detected during operation; or so forth. The correlation may be respective to an absolute value of the PUC signal characteristic, or may be respective to a fractional (e.g., percentage) change in the PUC signal characteristic.

With continuing reference to FIG. 1, once the calibration is completed the phantom is removed from the MR scanner 10 and is replaced by a subject, such as a human subject, a veterinary subject, a preclinical study subject, an archaelogical mummy, or so forth, and the subject undergoes the MR procedure. The safety monitoring module 20 further includes a PUC signal monitor 32 that monitors the PUC signal from each of the one or more pick-up coils as the subject undergoes the MR procedure. This monitoring is performed during the transmit phase of the MR sequence, which transmit phase may be repeated for repetition time (TR) of the MR sequence. The PUC signal detected during the transmit phase is compared with the unsafe condition criterion 30 by a “potentially unsafe condition” detector (also referred to as “unsafe condition detector”) 34. The MR procedure continues so long as the PUC signal does not satisfy the unsafe condition criterion 30.

If, however, the unsafe condition detector 34 detects an unsafe condition as indicated by the PUC signal satisfying the unsafe condition criterion 30, then an unsafe condition response sub-module 36 is invoked to perform one or more remedial actions, such as terminating the MR procedure, providing a displayed alarm informing MR operating personnel of the potentially unsafe condition, or so forth. Another contemplated unsafe condition response is to continue the MR procedure using a modified MR sequence that reduces the likelihood of implant device heating. For example, radio frequency transmit power may be reduced in order to reduce the SAR. This latter response can optionally be performed after authorization by the user—for example, temporarily terminating the procedure and displaying a warning that includes options for the user to stop or to continue with a modified MR sequence. It is also contemplated for the unsafe condition response sub-module 36 to modify the MR procedure automatically without user intervention, for example by modifying the MR sequence parameters and using the output of the monitoring components 32, 34 as feedback for optimizing the sequence parameters for safety. In this latter configuration, the user is optionally notified of the unsafe condition by an alarm indicator that also indicates the automatic remedial action that is taken by the unsafe condition response sub-module 36.

Advantageously, the safety monitoring of the subject undergoing the MR procedure can be performed in real time. In some embodiments, the monitored PUC signal characteristic is displayed in real time on a display 18a of the computer 18 during the performance of the MR procedure. Optionally, along with the real time display of the PUC signal characteristic, the unsafe condition criterion 30 may be displayed in a visually perceptible relationship with the real time display of the PUC signal characteristic. For example, the PUC signal characteristic can be plotted as a function of time, and if the unsafe condition criterion 30 is a threshold level then the unsafe condition criterion 30 can be suitably represented on the plot as a horizontal line denoting the threshold level.

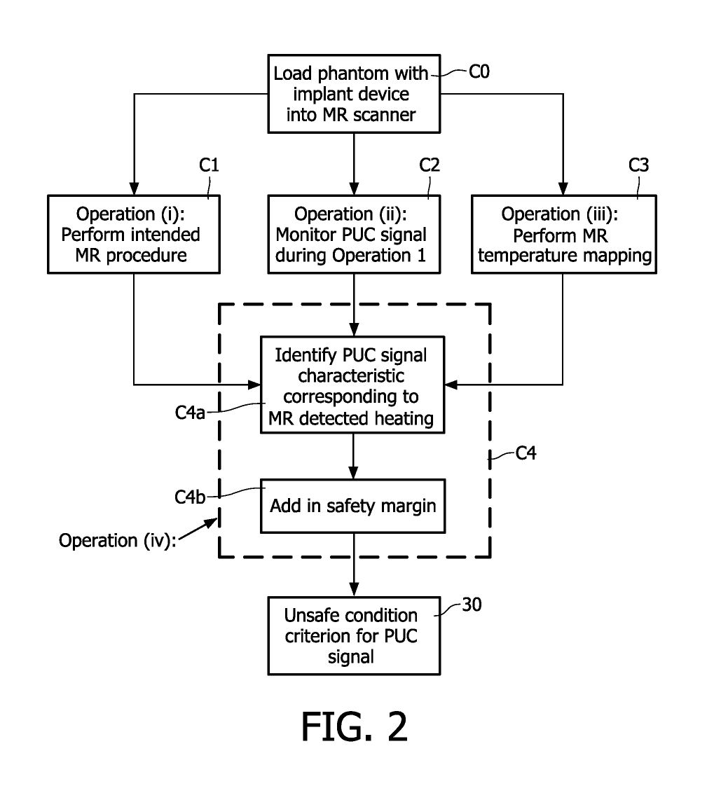

With continuing reference to FIG. 1 and with further reference to FIG. 2, an illustrative example of the calibration procedure starts with an operation C0 (also sometimes referred to herein as “subject loading operation”) in which the phantom or other calibration subject (which could be a human or veterinary subject) containing or otherwise including the implant device is loaded into the MR scanner 10. If a phantom is used as the calibration subject, then the phantom is preferably configured to mimic the subject, and to mimic the location, orientation, and other relevant aspects of the placement of the implant device in the subject. For example, if the subject to be monitored is a human subject and the implant device is a cardiac pacemaker, then the phantom may suitably be a standard ASTM phantom comprising a fat-water emulsion filling, in which a cardiac pacemaker of the same manufacturing model as the cardiac pacemaker in the human subject is disposed with placement in the phantom mimicking placement in the human subject, preferably including extension of the pacemaker wires in a fashion mimicking that of an operational pacemaker implanted in a human subject. The mimicking entails mimicking those aspects of the subject that are relevant for the MR procedure and its effects on the subject and on the implant device. For example, the phantom should have a general shape and size that mimics that of a human subject, but the phantom does not need to have the detailed facial features of the human subject, and may omit the clothing worn by the human subject if the clothing is not expected to impact the MR procedure, and so forth. Similarly, although using the same pacemaker model in the phantom as in the human subject is advantageous, it is also contemplated to employ a similar model that differs only in aspects unlikely to have substantial impact on the MR procedure or current induction in the pacemaker.

The intended MR procedure (that is, the MR procedure intended to be performed on the human subject) is then performed in an operation C1 (also sometimes referred to herein as “Operation (i)” or “MR procedure operation”). The MR procedure is defined at least by the employed MR sequence. The operation C1 of performing the intended MR procedure on the phantom may entail performing the intended MR procedure precisely as it is intended to be performed on the subject, or may entail performing the intended MR procedure with some modifications. For example, inductive heating of conductive parts of the implant device is most likely to occur during the transmit phase when substantial radio frequency power is being injected into the subject, whereas during the receive phase relatively little power may be injected. In such cases, the operation C1 of performing the intended MR procedure on the phantom may entail performing the transmit operations while omitting or shortening the readout phase. On the other hand, if the readout phase employs large magnetic field gradient slew rates, as for example may be the case in an echo-planar imaging (EPI) readout, then the operation C1 of performing the intended MR procedure on the phantom should preferably include the EPI readout or other readout that entails large magnetic field gradient slew rates. If the intended MR procedure is an interventional procedure in which the implant device is a catheter or biopsy needle that is inserted into the subject, then the operation C1 of performing the intended MR procedure on the phantom should preferably include inserting the catheter or biopsy needle into the phantom in a fashion mimicking the intended insertion of the catheter or biopsy needle into the subject of the interventional procedure.

During the operation C1 of performing the intended MR procedure on the phantom, an operation C2 (also sometimes referred to herein as “Operation (ii)” or “PUC signal monitoring operation”) is performed by the PUC signal monitor 32. The operation C2 comprises detecting a pick-up coil (PUC) signal at least during a radio frequency transmit phase. Optionally, if an EPI or other readout is employed which has some likelihood of inducing electrical current in conductive parts of the implant device, the operation C2 may also be performed during the readout phase or during other portions of the intended MR procedure that may cause such current induction.

To monitor the temperature of the implant device during the operation C1 of performing the intended MR procedure on the phantom, an operation C3 (also sometimes referred to herein as “Operation (iii)” or “temperature mapping operation”) is performed comprising performing three-dimensional temperature mapping of the phantom using a magnetic resonance sequence that is configured to detect any temperature increase induced in any part of the implant device by operation C1. Configuration of the temperature mapping operation C3 to detect any temperature increase induced in any part of the implant device by operation C1 entails at least performing the temperature mapping operation C3 close enough in time to the transmit phase of the intended procedure C1 so that any induced temperature increase has not yet dissipated before performing the temperature mapping operation C3. For example, in some embodiments the intended procedure C1 may be performed with the readout phase omitted, and the temperature mapping operation C3 can be performed in place of the readout phase. Additionally, the temperature mapping operation C3 is optionally configured to detect any temperature increase induced in any part of the implant device by operation C1 by employing a fast temperature mapping sequence, such as a fast PRF-based MR temperature mapping sequence. Enhanced temperature mapping speed may be obtained in some embodiments by using larger magnetic field gradients and so forth than might be advisable for temperature mapping of a human subject or other subject for which SAR exposure should be limited. However, care should be taken to ensure that the temperature mapping sequence does not itself induce electrical current in conductive parts of the implant device.

The operations C2, C3 provide calibration information for correlating the PUC signal characteristic with a temperature increase in any portion of the implant device. This correlation is performed by an operation or set of operations C4 (also sometimes referred to herein as “Operation (iv)” or “correlation operation”) by which an unsafe condition criterion for the detected PUC signal is generated based on correlating a PUC signal characteristic detected by the PUC signal monitoring operation (ii) C2 with a temperature increase detected by temperature mapping operation (iii) C3. More particularly, a first sub-operation C4a identifies a PUC signal characteristic that correlates with the observable onset or other selected minimal measure of heating of any part of the implant device as indicated by the temperature mapping operation C3. Because the heating of any part of the implant device is generally considered to be unsafe, the observable onset or other selected minimal measure of heating of any part of the implant device as indicated by the temperature mapping operation C3 should be based on a maximum local temperature anywhere in the temperature map of the implant device at any given time. Optionally, smoothing, curve fitting over time intervals, or other processing of the temperature data may be employed to reduce a likelihood of misinterpreting an erroneous temperature “blip” as a physical localized temperature rise.

The output of the sub-operation C4a is a PUC signal characteristic that is indicative of the onset or other “start” of a temperature rise. However, the heating of any part of the implant device is generally considered to be unsafe, and it would be preferable to detect incipient heating before it is detectable by the MR temperature mapping. Also there may be some finite time lag between onset of electrical current induction as observed by the PUC signal characteristic and consequent local heating as observed by the MR temperature mapping operation C3. For at least these reasons, employing the PUC signal characteristic output by the sub-operation C4a at the first observable temperature increase as the unsafe condition criterion may provide too little safety margin. In the embodiment illustrated in FIG. 2, the sub-operation C4a is followed by an optional further sub-operation C4b in which a safety margin is added in so as to generate the final unsafe condition criterion 30.

Operation C4 relies upon detection of a temperature increase for at least one part of the implant device. On the other hand, the intended MR procedure when performed on the subject is preferably configured to avoid any heating of any part of the implant device. The safety monitoring is intended to detect the abnormal condition in which incipient heating may be starting to occur despite precautions taken by medical personnel. Accordingly, the calibration operations C1, C2, C3 may be repeated with different parameters for the MR sequence used in the MR procedure operation C1 of performing the intended MR procedure on the phantom. Typically, parameters such as the radio frequency excitation power used during the transmit phase, the magnetic field gradient slew rate, or other parameters are increased from one iteration to the next to gradually increase the SAR or otherwise gradually enhance likelihood of electrical current induction in conductive parts of the implant device. If a phantom is used as the calibration subject, then there is no concern for the health or integrity of the phantom, and so such parameters can be increased with each iteration of the calibration operations C1, C2, C3 until the temperature mapping operation C3 detects a temperature rise in at least one part of the implant device. If a human calibration subject is used, then parameter adjustments should be monitored by iterations of the temperature mapping operation C3 to ensure safety of the human calibration subject.

Similarly, if the calibration subject is a phantom then the lack of concern for the health or integrity of the phantom enables the temperature mapping operation C3 to optionally be performed with relatively high SAR setting or the like, so long as the temperature mapping operation C3 does not itself induce heating of conductive parts of the implant device. In this way, the temperature mapping operation C3 can be performed relatively rapidly on the phantom as compared with performing the analogous operation on a human or animal subject. This in turn enables rapid detection of the onset of implant device heating.

PRF-based MR temperature mapping is generally a reliable method for MR temperature mapping/imaging provided that other sources of transient phase evolution, such as motion and system drift, can be compensated or held negligible. For the purpose of calibration operation C3, motion is generally not a concern since the phantom is an inanimate object. System drift, such as variation in the static (B₀) magnetic field, can be compensated for by using a fat-water emulsion filling for the phantom since fat does not have a weak temperature dependence of the proton resonance frequency. However, fat signal has other dependencies, such as a dependency on the static (B₀) magnetic field, which can be monitored so that the water PRF measurement can be spatially compensated for these effects. Adjustable SAR is provided by interleaving off-resonant high SAR pre-pulses with the actual PRF-based MR temperature mapping sequence, which typically has a low or moderate SAR.

The calibration illustrated in FIGS. 1 and 2 employs the three-dimensional temperature mapping operation C3 to detect an unsafe PUC signal characteristic, from which the unsafe condition criterion 30 is derived. This approach involves affirmatively generating an unsafe condition (preferably in a phantom for safety reasons) and determining the unsafe condition criterion 30 based on this affirmative unsafe condition information. This approach is useful, for example, in qualifying an implant device as MR conditional for specified MR imaging conditions. For example, a manufacturer can employ the calibration of FIG. 2 to affirmatively demonstrate a safe MR operating window for the manufacturer's implant device, where the unsafe condition criterion 30 delineates the safe MR operating window.

Other approaches besides the three-dimensional temperature mapping approach of FIGS. 1 and 2 can also be used to establish the unsafe condition criterion 30. For example, in another approach the phantom containing an implant device is replaced by a human subject who does not have an implant device, or for whom the intended magnetic resonance procedure is otherwise predetermined to be safe. This “safe” human subject is loaded into the MR scanner 10 analogous to the subject loading operation C0, and the intended MR procedure is performed analogous to the MR procedure operation C1 with the PUC signal monitored analogous to PUC signal monitoring operation C2—however, the MR temperature mapping operation C3 is optionally omitted since it is known a priori that the MR procedure is safe for this human subject. The correlation operation C4 is modified in this alternative approach as follows. The detected PUC signal characteristic (for example, PUC signal amplitude, PUC signal phase, PUC signal cross-coupling, or so forth) is known to represent a “safe” PUC signal characteristic since it is known that the intended MR procedure is safe for this safe human calibration subject. The unsafe condition criterion 30 is then suitably defined as a selected deviation (for example, a percentage deviation) from the PUC signal characteristic detected by the PUC signal monitoring analogous to the PUC signal monitoring operation C2. The unsafe condition criterion 30 generated by this alternative approach is independent of the implant device since the calibration does not utilize an implant device. However, the PUC signal characteristic detected for the “safe” human calibration subject may depend on the body dimensions (body size, body weight, body aspect ratio, or so forth) of the human calibration subject. Accordingly, this alternative calibration approach is preferably performed for “safe” human calibration subjects of a variety of different body dimensions in order to determine a safe PUC signal characteristic and corresponding unsafe condition criterion 30 for various different body dimensions. If additionally a plurality of subjects of a given body dimension “bin” are used in the calibration, then the variance or spread of the PUC signal characteristic amongst the plurality of subjects of the given body dimension “bin” can be used to select the deviation from the average PUC signal characteristic that defines the unsafe condition criterion 30. For example, if the average PUC signal amplitude for human calibration subjects falling within the selected body dimension bin is Sₒ within a variation of +5%, then the unsafe condition criterion 30 might, for example, be set to any PUC signal amplitude that falls outside of the known “safe” range of S₀±5%.

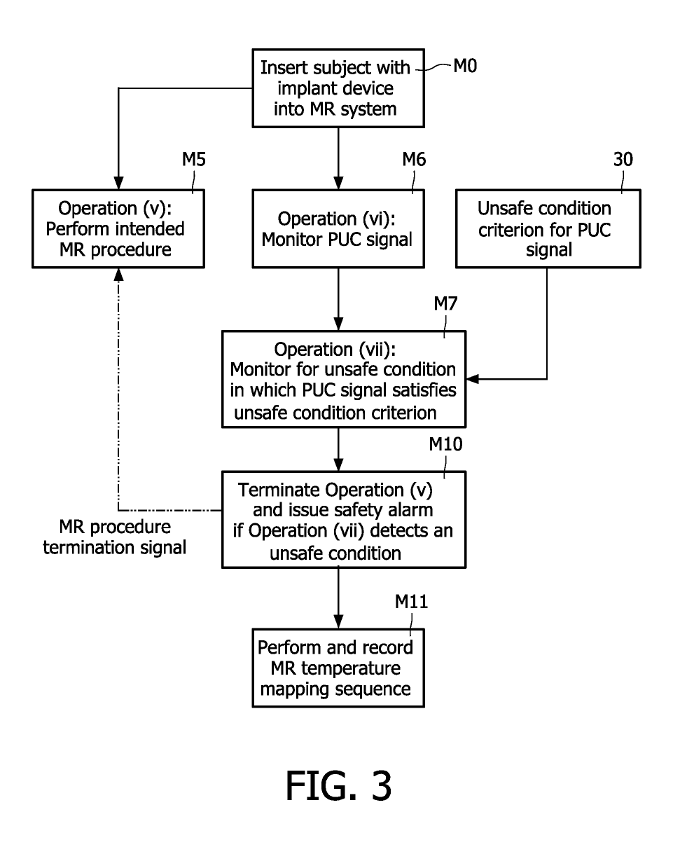

With continuing reference to FIG. 1 and with further reference to FIG. 3, an illustrative example of the monitoring of the MR procedure as applied to the subject starts with a subject insertion operation M0 in which the subject is loaded into the MR scanner 10. The subject also contains (that is, has implanted therein) the implant device. It is contemplated for the implant device in the subject to be the same as the implant device in the phantom (for example, removed from the phantom after calibration and then implanted in the subject). More typically, however, the implant device in the subject is not the same device as the implant device in the phantom, but is a similar device at least with respect to its likely characteristics under MR. For example, the implant device in the subject may be a different cardiac pacemaker from the cardiac pacemaker in the phantom, but both pacemakers may be the same manufacturing model, or both may be similar manufacturing models (e.g., about the same size and dimensions, same number and arrangement of leads or wires extending from both pacemakers, and so forth).

The intended MR procedure is performed on the subject in operation M5 (also sometimes referred to herein as “Operation (v)” or “intended MR procedure operation”). The intended MR procedure typically has a practical purpose such as acquiring MR images of the subject, or monitoring or tracking insertion of an interventional instrument into the subject, or acquiring metabolic information about the subject through MR spectroscopy, or so forth.

During the operation M5 of performing the intended MR procedure on the subject, an operation M6 (also sometimes referred to herein as “Operation (vi)” or “PUC monitoring operation”) is performed by the PUC signal monitor 32. The operation M6 comprises detecting a pick-up coil (PUC) signal at least during a radio frequency transmit phase. Optionally, if an EPI or other readout is employed which has some likelihood of inducing electrical current in conductive parts of the implant device, the operation M6 may also be performed during the readout phase or during other portions of the intended MR procedure that may cause such current induction.

In an operation M7 (also sometimes referred to herein as “Operation (vii)” or “unsafe condition monitoring operation”) the potentially unsafe condition detector 34 monitors the PUC signal to determine whether a PUC signal characteristic satisfies the unsafe condition criterion 30. As long as operation M7 does not detect an unsafe condition, the operation M5 of performing the intended MR procedure continues. However, if operation M7 does detect an unsafe condition, then the unsafe condition response sub-module 36 is invoked to perform a termination operation M10 which sends a termination signal to cause the operation M5 of performing the intended MR procedure to terminate, and provides a suitable human-perceptible alarm or notification to inform the MR system operator of the detected potentially unsafe condition. Optionally, an operation M11 (also sometimes referred to herein as “temperature recording operation”) also is performed, which comprises performing the MR temperature mapping sequence used in calibration operation C3 (see FIG. 2), but with low SAR settings, and recording the acquired temperature map of the subject. The temperature recording operation M11 can be useful to document the actual heating, if any, of the implant device in the subject. Because of the safety margin added to the unsafe condition criterion 30 in operation C4b (see FIG. 2), it is likely that no measurable temperature rise will be detected by the operation M11 for any part of the implant device. This provides assurance that early detection of the incipient unsafe situation by the operations M6, M7 and consequent termination operation M10 ensured that the subject likely incurred no harm or damage. The remedial actions M10, M11 are illustrative, and other remedial actions are contemplated, such as continuing the MR sequence with parameters adjusted to reduce a likelihood of implant device heating.

The monitoring operations M6, M7 performed by the monitoring components 30, 34 can operate in various ways. In one approach, the values of the PUC signals of the one or more pickup coils are monitored independently and each PUC signal is compared with an unsafe condition criterion corresponding to that PUC signal. If there are multiple pickup coils (for example, corresponding to elements of a transmit coil array) then the potentially unsafe condition detector 34 can suitably detect an unsafe condition responsive to any PUC signal meeting its corresponding unsafe condition criterion. Alternatively, it can be required that two or more PUC signals (or three or more PUC signals, or so forth) meet their corresponding unsafe condition criteria in order to indicate an unsafe condition. This latter approach provides robustness against a “glitch” or other outlier measurement of a PUC signal.

If multiple pickup coils are monitored, then it is also contemplated to consider cross-coupling parameters in assessing the PUC signals for an unsafe condition. For example, in one approach one transmit channel at a time sends a short pulse and the PUC signals are monitored responsive to the pulse, and this is repeated for each transmit channel to generate a “system matrix” whose elements (i, j) are indicative of cross-coupling between the i-th (i^{th}) and j-th (j^{th}) transmit channels. Without being limited to any particular theory of operation, it is believed that cross-coupling may have even greater sensitivity to implant device heating as compared with the response of a single pickup coil, since electrical current flowing in a portion of the implant device can contribute strongly to cross-coupling between pickup coils. In these embodiments, the unsafe condition criterion 30 is embodied as a cross-coupling parameter threshold value, and is suitably calibrated as already described with reference to FIG. 2 where the PUC signal characteristic C4a corresponding to MR detected heating is a system matrix element value.

With reference back to FIG. 1, the disclosed modules 12, 14, 20 can be embodied by any suitably programmed digital processor or combination of digital processors and application-specific integrated circuitry (ASIC). In some embodiments, the safety monitoring module 20 is a component of the MR control module 12, for example both being embodied by a singular processor, while in other embodiments the modules 12, 20 may be embodied by separate processors. The reconstruction module 14 may be variously embodied together with the MR control module 12, together with the safety monitoring module 20, or as a third separate processor.

Moreover, in storage media embodiments, a storage medium such as a magnetic disk, optical disk, electrostatic memory, random access memory (RAM), read-only memory (ROM), various combinations thereof, or so forth, stores instructions executable by a digital processor to perform one or more embodiments of the disclosed magnetic resonance methods.

In some illustrative embodiments, the disclosed modules 12, 14, 20 are suitably embodied by one or more digital processors which are components of the illustrated computer 18 and which are programmed by software stored on a hard disk drive, optical disk, or other storage medium of or accessible to the computer 18 to perform one or more embodiments of the disclosed magnetic resonance methods.

Some actually performed safety monitoring operations are described next. For these experiments, a whole body 3T MR scanner (based on Achieva™ magnetic resonance scanner, available from Philips Healthcare, Netherlands) was used. The scanner was equipped with eight parallel radio frequency transmit channels (the word “parallel” as used herein refers to the concept of “parallel imaging” employing multiple channel transmit RF coils) and an 8-channel real-time radio frequency transmission monitoring system with eight pick-up coils (PUCs) to measure the complex currents of each of the eight RF transmit elements of a multi-channel body coil (MBC). The PUCs were calibrated prior to the experiment to have identical signal strength and intensity output. The MR scanner was also equipped with a modified patient table that allowed for continuous, reproducible table movement during MR data acquisition. The intended MR sequence for these experiments employed a low SAR scan (FFE, TR=160 ms, TE=3.5 ms, α=30°, whole body SAR<0.1 W/kg) with the phantom or subject moving into the final imaging position under automatic control of the patient support system, advancing with a constant (adjustable) velocity of 50 mm/s.

For the phantom calibration, several cardiac pacemaker devices, with connected or disconnected leads (the latter mimicking a broken lead) of different types and length were used. They were disposed in a tubular, water-filled phantom and moved into the MR scanner while being monitored with the pick-up coils. For these experiments, the PUC signals detected during the radio frequency transmit pulses were displayed on a real-time graphical user interface (GUI) for visual inspection. The experiments were repeated for different locations of the cardiac pacemaker device in the MR scanner as well as for a high SAR MR sequence with the device at a fixed position. For verification purposes during these experiments, the PUC signal was acquired simultaneously with temperature measurements using a fiber-optic temperature measurement setup (Luxtron790, LumaSense Technologies, Santa Clara, Calif., USA) at the tip of the pacemaker lead. As shown in FIGS. 1-3, such a fiber-optic temperature measurement sensor is generally not required or used, since the MR temperature mapping provides more holistic temperature information over the entire implant device.

The temperature mapping operation C3 employed a single slice gradient echo EPI sequence (TR=100 ms, TE=15 ms, FOV 300×300 mm³, voxel size 2.5×2.5×6 mm³, flip angle=40°). An off-resonance magnetization transfer contrast (MTC) pre-pulse with an off-resonance frequency of 1100 Hz and 1000 degrees flip angle was added to adjust the whole body SAR to 4.0 W/kg. The temperature mapping experiment was controlled via a real-time interactive GUI with color image overlay over the magnitude images. It employed conventional PRF MR temperature mapping with additional drift corrections based on selective fat imaging.

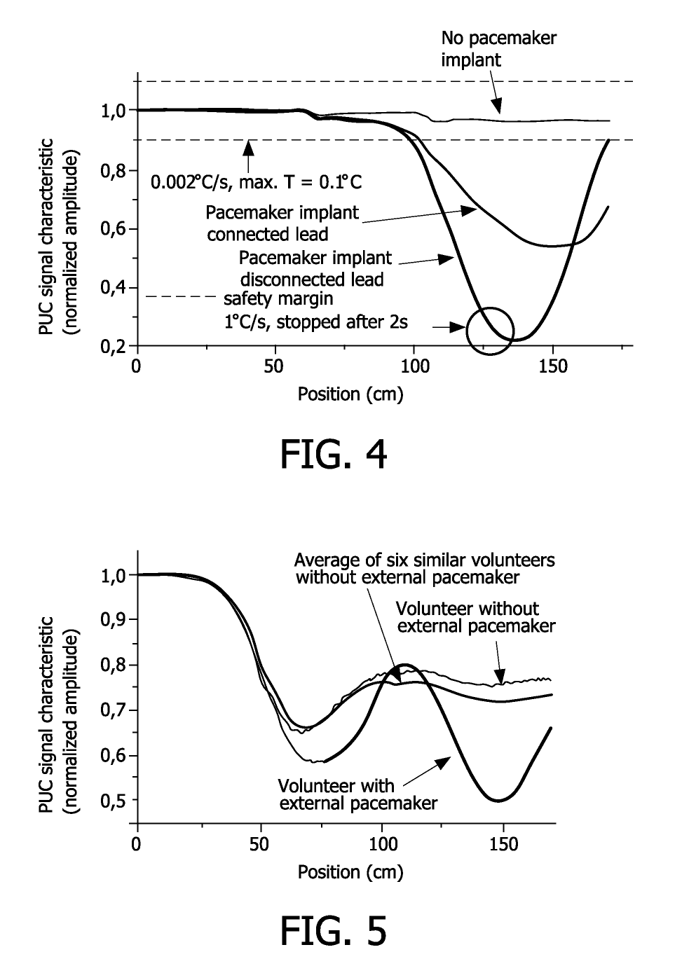

With reference to FIG. 4, most devices in these experiments caused readily detectable changes in the PUC signals. FIG. 4 plots the PUC signal characteristic (normalized amplitude) versus position (in centimeters) as the phantom is moved using the movable subject table. In this case, a drop of the PUC signal characteristic of about 80% was observed when the pick-up coil was nearest to the implanted pacemaker. Using a high SAR sequence, a 0.1° C. increase in temperature was measured for positions 0-100 cm as indicated in FIG. 4. Thus, between positions 0-100 cm, negligible change is observed by both the PUC signal and by the MR temperature mapping. However, at the location marked in FIG. 4 with a circle, corresponding to a large decrease in the PUC signal characteristic, a temperature increase of 2° C. was obtained in 2.8 s using the MR temperature mapping, indicating correlation of strong RF coupling as measured by the PUC signal and substantial device-induced heating as measured by the MR temperature mapping. For defining the unsafe condition criterion 30, a safety margin of 10% was added by the operation C4b (see FIG. 2), as indicated in FIG. 4.

With reference to FIG. 5, to verify the monitoring phase, in an actually performed in-vivo experiment eight healthy male volunteers were scanned. To avoid actually implanting the pacemakers in the human volunteers, the pacemakers were instead arranged externally but close to the volunteer's abdominal body region to simulate an implanted pacemaker. The experiment was performed without a pacemaker, and with a resonant combination of a pacemaker and lead placed next to the arms and legs similar to the phantom experiment. Here it was found that the detected PUC signal characteristic (normalized amplitude) for six volunteers with similar weight and height (mean weight=80 kg, mean height=1.83 m) agreed well in terms of the root mean square error (RMSE). The RMSE between the averaged PUC signals and the PUC signals of the individual volunteers were in the range of 0.28-0.59. FIG. 5 shows the PUC signal characteristic (normalized amplitude) for one volunteer with an RMSE of 0.36, along with a plot of the average PUC signal characteristic for the six similar volunteers without a pacemaker. When the volunteers were holding one of the tested implantable devices close to their abdominal body region to simulate an implanted pacemaker, a statistically significant difference was detected. Consequently, the RMSE between the mean curves of the volunteer PUC signals and the signal for an individual volunteer holding a device was determined as 1.42-1.78. In this way, volunteers holding the resonant pacemaker close to their body could be readily distinguished from a volunteer ensemble without pacemakers.

The safety monitoring system can be calibrated for patients of different weights and sizes. In one suitable approach, multiple persons (e.g., volunteers) of similar body dimensions are measured and the results are averaged to generate a reference for those body dimensions (e.g., weight, height, diameter). This is repeated for multiple groups of people of different body dimensions so as to generate a database for calibrating the influence of body dimensions. Instead of using persons or volunteers, it is also contemplated to perform the calibration using phantoms of different “body” dimensions for the calibration, as described for example with reference to FIG. 2. When performing the safety monitoring described with reference to FIG. 3, the appropriate calibration data for the body dimensions of the specific subject undergoing monitoring are loaded from the database, for example based on inputted values of the body dimensions of the subject to undergo monitoring or based on an initial “whole body” magnetic resonance scan of the subject performed to determine the body dimensions.

The invention has been described with reference to the preferred embodiments. Modifications and alterations may occur to others upon reading and understanding the preceding detailed description. It is intended that the invention be construed as including all such modifications and alterations insofar as they come within the scope of the appended claims or the equivalents thereof. In the claims, any reference signs placed between parentheses shall not be construed as limiting the claim. The word “comprising” does not exclude the presence of elements or steps other than those listed in a claim. The word “a” or “an” preceding an element does not exclude the presence of a plurality of such elements. The disclosed method can be implemented by means of hardware comprising several distinct elements, and by means of a suitably programmed computer. In the system claims enumerating several means, several of these means can be embodied by one and the same item of computer readable software or hardware. The mere fact that certain measures are recited in mutually different dependent claims does not indicate that a combination of these measures cannot be used to advantage.

1. A magnetic resonance method comprising:
(i) performing (C1) a magnetic resonance procedure on a calibration subject;
(ii) detecting (C2) a pick-up coil (PUC) signal at least during a radio frequency transmit phase of operation (i); and
(iv) generating (C4) an unsafe condition criterion (30) based on the detected PUC signal.

2. The magnetic resonance method as set forth in claim 1, wherein the magnetic resonance procedure is predetermined to be safe for the calibration subject, and the generating operation (iv) (C4) comprises:
generating the unsafe condition criterion (30) as a selected deviation from a PUC signal characteristic detected by operation (ii).

3. The magnetic resonance method as set forth in claim 2, wherein the calibration subject does not include an implant device.

4. The magnetic resonance method as set forth in claim 1, wherein the calibration subject includes an implant device, the method further comprising:
(iii) performing (C3) three-dimensional temperature mapping of the calibration subject using a magnetic resonance sequence that is configured to detect a temperature change induced in any part of the implant device by operation (i);
wherein the generating operation (iv) (C4) generates the unsafe condition criterion (30) based on correlating a PUC signal characteristic detected by operation (ii) with a temperature change detected by operation (iii).

5. The magnetic resonance method as set forth in claim 4, wherein operation (i) (C1) is repeated with different magnetic resonance sequence parameters until operation (iii) (C3) detects a temperature change induced in at least one part of the implant device.

6. The magnetic resonance method as set forth in claim 4, wherein operation (iv) (C4) comprises:
correlating (C4a) a PUC signal characteristic detected by operation (ii) (C2) with a temperature change detected by operation (iii) (C3); and
generating the unsafe condition criterion (30) by adding (C4b) a selected safety margin to the correlated PUC signal characteristic.

7. The magnetic resonance method as set forth in claim 4, wherein the operation (iv) (C4) generates an unsafe condition criterion (30) for the detected PUC signal based on correlating at least one of (i) a decrease in PUC signal amplitude and (ii) a change in PUC signal phase detected by operation (ii) (C2) with a temperature change detected by operation (iii) (C3).

8. The magnetic resonance method as set forth in claim 4, wherein operation (iii) (C3) comprises:
(iii) performing three-dimensional temperature mapping of the calibration subject using a proton resonance frequency (PRF) based magnetic resonance sequence that is configured to detect a temperature change induced in any part of the implant device by operation (i) (C1).

9. The magnetic resonance method as set forth in claim 8, wherein the calibration subject includes fat and water components and operation (iii) (C3) includes PRF adjustment based on the fat and water component MR signals.

10. A magnetic resonance method comprising:
(v) performing (M5) a magnetic resonance procedure on a subject containing an implant device;
(vi) detecting (M6) a PUC signal at least during a radio frequency transmit phase of operation (v); and
(vii) monitoring (M7) for an unsafe condition during the operation (v) indicated by the PUC signal detected in operation (vi) satisfying an unsafe condition criterion (30).

11. The magnetic resonance method as set forth in claim 10, wherein the unsafe condition criterion (30) is generated by a method as set forth in any one of claim 1-9.

12. The magnetic resonance method as set forth in claim 11, wherein operations (i), (ii), and (iv) (C1, C2, C4) are performed using calibration subjects of different body dimensions to generate unsafe condition criterion (30) for the detected PUC signal for subjects of different body dimensions, and monitoring operation (vii) (M7) further includes selecting the unsafe condition criterion (30) for the detected PUC signal corresponding to a body dimension of the subject of performing operation (v) (M5).

13. The magnetic resonance method as set forth in claim 1, wherein:
the operation (ii) (C2) comprises detecting a plurality of PUC signals from a plurality of pick-up coils at least during a radio frequency transmit phase of operation (i) (C1); and
the operation (iv) (C4) generates an unsafe condition criterion (30) for the detected plurality of PUC signals based on at least one coil-to-coil coupling identified based on the plurality of PUC signals detected by operation (ii) (C2).

14. A digital storage medium storing instructions executable by a digital processor to perform a magnetic resonance method as set forth in claim 1.

15. A magnetic resonance system comprising:
a magnetic resonance scanner (10); and
a processor (12, 14, 20) configured to operate in cooperation with the magnetic resonance scanner to perform a magnetic resonance method as set forth in claim 1.

16. A magnetic resonance system comprising:
a magnetic resonance scanner; and
a processor configured to operate in cooperation with the magnetic resonance scanner to perform a magnetic resonance method as set forth in claim 10.

17. A magnetic resonance system comprising:
a magnetic resonance scanner; and
a processor configured to operate in cooperation with the magnetic resonance scanner, and further configured to:
perform a magnetic resonance procedure on a calibration subject;
detect a pick-up coil signal at least during a radio frequency transmit phase associated with the performance of the magnetic resonance procedure on the calibration subject; and
generate an unsafe condition criterion based on the detected pick-up coil signal.

18. The magnetic resonance system as set forth in claim 17, wherein the calibration subject does not include an implant device.

19. The magnetic resonance system as set forth in claim 17, wherein the calibration subject includes an implant device, and wherein the processor is further configured to:
perform three-dimensional temperature mapping of the calibration subject using a magnetic resonance sequence that is configured to detect a temperature change induced in any part of the implant device; and
generate the unsafe condition criterion based on correlating a pick-up coil signal characteristic with the detected temperature change.

20. The magnetic resonance system as set forth in claim 19, wherein the processor is further configured to repeat the magnetic resonance procedure on the calibration subject with different magnetic resonance sequence parameters.
